(19) United States
(12) Patent Application Publication
(10) Pub. No.: US 2025/0248283 A1
(43) Pub. Date: Jul. 31, 2025

(54) DISPLAY DEVICE

(71) Applicant: LG Display Co., Ltd., Seoul (KR)

(72) Inventors: JiSub PARK, Gumi-si (KR); Byeonggon KIM, Daegu (KR); Cheolhyeon KIM, Busan (KR); Youngchul SHIN, Daegu (KR)

(73) Assignee: LG Display Co., Ltd., Seoul (KR)

(21) Appl. No.: 18/936,610

(22) Filed: Nov. 4, 2024

(30) Foreign Application Priority Data
Jan. 26, 2024 (KR) 10-2024-0012385

(51) Int. Cl. H10K 59/80; H10K 59/122; H10K 102/00

(52) U.S. Cl. CPC H10K 59/877; H10K 59/122; H10K 2102/341

(57) ABSTRACT

A display device can include a substrate having a plurality of sub pixels, a planarization layer disposed on the substrate and having a first open area, an anode electrode disposed in the first open area and a side portion of the planarization layer adjacent to the first open area, a bank configured to expose a part of the anode electrode and having a second open area corresponding to the first open area, a recrystallization layer disposed on the bank and including a fluoro-group, an organic layer disposed on the anode electrode exposed by the second open area, and a cathode electrode disposed on the organic layer and the recrystallization layer. By this configuration, the front efficiency and the color viewing angle of the display device can be improved.

### CROSS-REFERENCE TO RELATED APPLICATIONS

This application claims priority to Korean Patent Application No. 10-2024-0012385 filed on Jan. 26, 2024, in the Korean Intellectual Property Office, the entire contents of which is hereby expressly incorporated by reference into the present application.

### BACKGROUND

### Field

The present disclosure relates to a display device.

### Discussion of the Related Art

In the information era, a field of a display device which visually expresses electrical information signals has been rapidly developed and thus, studies are continued to improve performances of various display devices, such as for providing a thin-thickness, a light weight, and low power consumption.

A representative display device can include a liquid crystal display (LCD) device, a field emission display (FED) device, an electro-wetting display (EWD) device, and an organic light emitting display (OLED) device.

An electroluminescent display device can be an organic light emitting display device, which can be a self-emitting display device since a separate light source is not necessary, which is different from a liquid crystal display device. Therefore, the electroluminescent display device can be manufactured to have a light weight and a small thickness. Further, since the electroluminescent display device is advantageous not only in terms of power consumption due to the low voltage driving, but also in terms of color implementation, a response speed, a viewing angle, a contrast ratio (CR), it is expected to be utilized in various fields.

The electroluminescent display device provides a plurality of light emitting diodes by disposing a plurality of organic layers each including an emission layer between two electrodes of an anode electrode and a cathode electrode. For example, when holes are injected from the anode electrode into the emission layer and electrons are injected from the cathode electrode into the emission layer, the injected electrons and holes are recombined in the emission layer to form excitons and emit light.

However, the electroluminescent display device can have a problem in that among the light emitted from the emission layer, some light does not go out from the display panel and can be trapped in the display panel. As such, the light extraction efficiency of the electroluminescent display device can be degraded to reduce a luminous efficiency.

### SUMMARY OF THE DISCLOSURE

An object to be achieved by aspects of the present disclosure is to provide a display device which improves a light extraction efficiency and improves a color viewing angle.

Another object to be achieved by aspects of the present disclosure is to provide a display device with an improved reliability.

Objects of the present disclosure are not limited to the above-mentioned objects, and other objects, which are not mentioned above, can be clearly understood by those skilled in the art from the following descriptions.

In order to achieve the objects as described above and other objects, according to an aspect of the present disclosure, a display device can include a substrate including a plurality of sub pixels, a planarization layer disposed on the substrate and having a first open area, an anode electrode disposed in the first open area and a side portion of the planarization layer adjacent to the first open area, a bank configured to expose a part of the anode electrode and having a second open area corresponding to the first open area, a recrystallization layer disposed on the bank and including a fluoro-group, an organic layer disposed on the anode electrode exposed by the second open area, and a cathode electrode disposed on the organic layer and the recrystallization layer.

Other detailed matters of the example embodiments are included in the detailed description and the drawings.

According to an aspect of the present disclosure, an anode electrode includes a side mirror structure to provide a display device with an excellent luminous efficiency. Accordingly, the low power is implemented to reduce the power consumption. Further, a green-house gas generated in accordance with the usage of the power is reduced to implement environment/social/governance (ESG).

According to an aspect of the present disclosure, a recrystallization layer including a fluoro-group is formed on the bank to adsorb or block outgas of the bank or the planarization layer, thereby improving the reliability of the display device.

According to an aspect of the present disclosure, the recrystallization layer is subject to a low-temperature heat treatment to increase a surface roughness, thereby improving a front efficiency and a color viewing angle according to the increase of the light extraction.

The effects according to aspects of the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram of a display device according to example embodiments of the present disclosure;

FIG. 2 is a circuit diagram of a sub pixel of a display device according to example embodiments of the present disclosure;

FIG. 3 is a view illustrating a pixel structure of a display device according to a first example embodiment of the present disclosure;

FIG. 4 is a view illustrating a cross-sectional structure of a display panel according to the first example embodiment of the present disclosure;

FIG. 5 is a view illustrating an emission image according to the first example embodiment of the present disclosure;

FIG. 6 is a view illustrating a cross-sectional structure of a display panel according to a second example embodiment of the present disclosure;

FIG. 7 is a view illustrating a pixel structure of a display device according to a third example embodiment of the present disclosure;

FIGS. 8A and 8B are views illustrating a cross-section of a display panel according to the third example embodiment of the present disclosure;

FIG. 9 is a view illustrating a pixel structure of a display device according to a fourth example embodiment of the present disclosure; and

FIGS. 10A and 10B are views illustrating a cross-section of a display panel according to the fourth example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure.

Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

Further, the term “can” fully encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device according to all embodiments of the present disclosure are operatively coupled and configured.

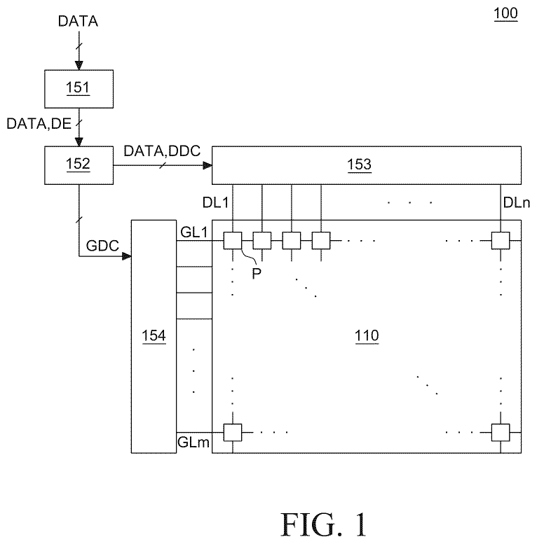

FIG. 1 is a block diagram of a display device according to example embodiments of the present disclosure.

Referring to FIG. 1, a display device 100 according to example embodiments of the present disclosure can include a display panel 110, an image processor 151, a timing controller 152, a data driver 153, and a gate driver 154.

The image processor 151 can output a data signal DATA and a data enable signal DE by a data signal DATA supplied from the outside.

The image processor 151 can output one or more of a vertical synchronization signal, a horizontal synchronization signal, and a clock signal in addition to the data enable signal DE.

The timing controller 152 is supplied with the data signal DATA together with a driving signal including the data enable signal DE or the vertical synchronization signal, the horizontal synchronization signal, and the clock signal, from the image processor 151. The timing controller 152 can output a gate timing control signal GDC for controlling an operation timing of the gate driver 154 and a data timing control signal DDC for controlling an operation timing of the data driver 153, based on the driving signal.

The data driver 153 samples and latches the data signal DATA supplied from the timing controller 152 in response to the data timing control signal DDC supplied from the timing controller 152 to convert the data signal into a gamma reference voltage and output the converted gamma reference voltage. The data driver 153 can output the data signal DATA through data lines DL1 to DLn, where n is a real number such as a positive integer.

Further, the gate driver 154 can output the gate signal while shifting a level of the gate voltage, in response to the gate timing control signal GDC supplied from the timing controller 152. The gate driver 154 can output the gate signal through gate lines GL1 to GLm, where m is a real number such as a positive integer.

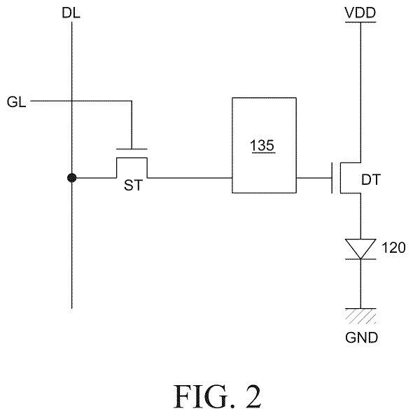

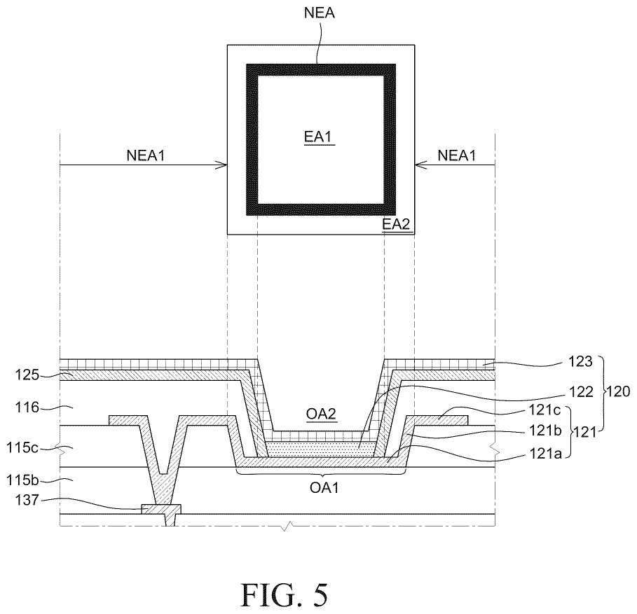

The display panel 110 includes a plurality of sub pixels P and can display images while each sub pixel P emits light in response to the data signal DATA and the gate signal supplied from the data driver 153 and the gate driver 154. A detailed structure of the sub pixel P will be described with reference to FIGS. 2 and 5.

FIG. 2 is a circuit diagram of a sub pixel of a display device according to example embodiments of the present disclosure. The sub pixel configuration of FIG. 2 can be used in each sub pixel P of the display device 100 or the like.

Referring to FIG. 2, the sub pixel of the display device according to the example embodiments of the present disclosure can include a switching transistor ST, a driving transistor DT, a compensation circuit 135, and a light emitting diode 120.

The light emitting diode 120 can operate to emit light in accordance with a driving current formed by the driving transistor DT.

The switching transistor ST can perform a switching operation such that a data signal supplied through the data line DL is stored in a capacitor as a data voltage in response to a gate signal supplied through the gate line GL.

Further, the driving transistor DT can operate to flow a predetermined driving current between a high potential power line VDD and a low potential power line GND in response to a data voltage stored in the capacitor.

The compensation circuit 135 is a circuit for compensating for a threshold voltage of the driving transistor DT and can include one or more thin film transistors and capacitors. A configuration of the compensation circuit 135 can vary depending on a compensating method.

The sub pixel illustrated in FIG. 2 is configured by a 2T (transistor) 1C (capacitor) structure including a switching transistor ST, a driving transistor DT, a capacitor, and a light emitting diode 120. When the compensation circuit 135 is added, the sub pixel can be formed in various forms, such as 3T1C, 4T2C, 5T2C, 6T1C, 6T2C, 7T1C, and 7T2C.

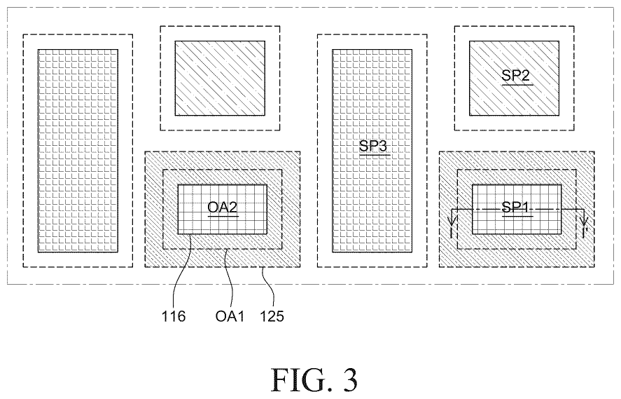

FIG. 3 is a view illustrating a pixel structure of a display device according to a first example embodiment of the present disclosure.

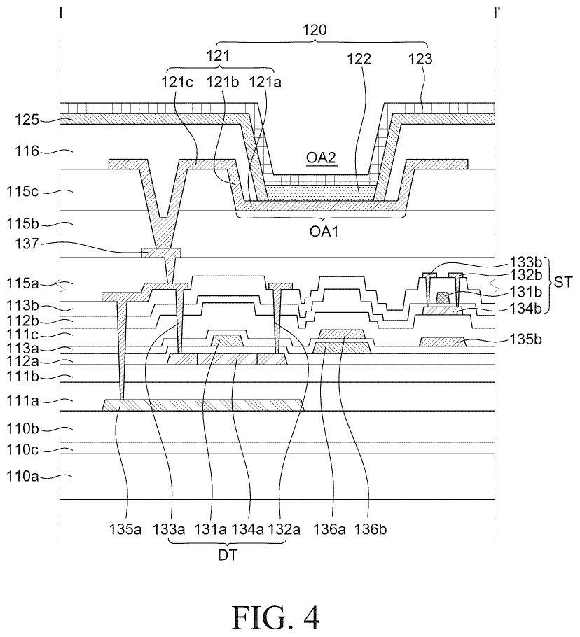

FIG. 4 is a view illustrating a cross-sectional structure of a display panel of the display device according to the first example embodiment of the present disclosure.

FIG. 5 is a view illustrating an emission image according to the first example embodiment of the present disclosure.

Particularly, FIG. 3 illustrate a part of the display panel in which six sub pixels SP1, SP2, and SP3 are disposed and illustrates a bank 116 including a second open area OA2 which is a main emission area, a first open area OA1 including a main emission area and a reflective emission area, and a recrystallization layer 125.

FIG. 4 illustrates a cross-section of the first sub pixel SP1 along line I-I′ of FIG. 3. Even though in FIG. 4, components above the light emitting diodes are not illustrated for the sake of convenience, the present disclosure is not limited thereto and the present disclosure can include an encapsulation layer and a touch sensor layer above the light emitting diode 120.

FIG. 5 illustrates a part a of cross-sectional structure of the first sub pixel SP1 illustrated in FIG. 4 and an emission image corresponding thereto.

Referring to FIG. 3, the display panel according to the first example embodiment of the present disclosure can include a pixel area in which a plurality of sub pixels SP1, SP2, and SP3 is provided and a wiring area in which various signal lines are disposed.

A plurality of first sub pixels SP1, second sub pixels SP2, and third sub pixels SP3 can be disposed in the pixel area. For example, the first sub pixel SP1 can be a red sub pixel. For example, the second sub pixel SP2 can be a green sub pixel. For example, the third sub pixel SP3 can be a blue sub pixel.

For example, the first sub pixel SP1, the second sub pixel SP2, and the third sub pixel SP3 can have a circular shape or a polygonal shape, but are not limited thereto. Here, a shape of the sub pixels SP1, SP2, and SP3 is defined by the planar shape of the anode electrode 121, but the present disclosure is not limited there.

In FIG. 3, one first sub pixel Sp1, one second sub pixel SP2, and one third sub pixel SP3 are gathered to configure one pixel, but is not limited thereto.

In the meantime, according to the present disclosure, due to the side mirror SM structure of the anode electrode 121, a reflective emission area is added as well as a main emission area so that the emission area can be expanded as compared with each of the sub pixels SP1, SP2, and SP3.

According to the first example embodiment of the present disclosure, a recrystallization layer 125 is formed above the bank 116 which covers the anode electrode 121 with a side mirror structure to adsorb or block outgas of the bank 116 or the planarization layers 115a, 115b, and 115c. By doing this, a reliability of the display device can be improved. For example, the bank 116 is formed after forming the anode electrode 121 and at this time, outgas which affects the reliability can be generated from the bank 116. The anode electrode 121 can reduce outgas generated in the planarization layers 115a, 115b, and 115c to some extent. However, in the case of a metal layer, there is a plurality of pin holes so that it is difficult to completely block the outgas.

Therefore, the recrystallization layer 125 is formed above the bank 116 to significantly reduce the outgas generated in the bank 116 or the planarization layers 115a, 115b, and 115c. However, even though in FIG. 3, an example that the recrystallization layer 125 is formed in the first sub pixel SP1 is illustrated, it is not limited thereto. Therefore, the recrystallization layer 125 can be formed in all the first sub pixel SP1, the second sub pixel SP2, and the third sub pixel SP3 or the recrystallization layer 125 can be formed in some of the first sub pixel SP1, the second sub pixel SP2, and the third sub pixel SP3.

Specifically, referring to FIGS. 4 and 5, the driving transistor DT, the switching transistor ST, and the light emitting diode 120 can be disposed above substrates 110a, 110b, and 110c.

For example, the substrates 110a, 110b, and 110c can include a first substrate 110a, a second substrate 110b, and an interlayer insulating film 110c. The interlayer insulating film 110c can be disposed between the first substrate 110a and the second substrate 110b. However, the present disclosure is not limited thereto and a single layered substrate can be provided or an interlayer insulating film may not be disposed between the first substrate 110a and the second substrate 110b.

As described above, the substrates 110a, 110b, and 110c include a first substrate 110a, a second substrate 110b, and an interlayer insulating layer 110c to suppress permeation of the moisture. For example, the first substrate 110a and the second substrate 110b can be polyimide (PI) substrates.

Transistors, such as a driving transistor DT or a switching transistor ST can be disposed above the substrates 110a, 110b, and 110c.

A multi-buffer layer 111a is disposed on the second substrate 110b and an active buffer layer 110b can be disposed on the multi-buffer layer 111a. However, the present disclosure is not limited thereto and a single layered buffer layer can be provided or a buffer layer may not be provided.

A first light shielding layer 135a can be disposed above the second substrate 110b. However, it is not limited thereto and the first light shielding layer 135a can be disposed on the multi-buffer layer 111a.

The first light shielding layer 135a can serve as a light shield.

The multi-buffer layer 111a can be disposed on the first light shielding layer 135a.

The active buffer layer 111b can be disposed on the multi-buffer layer 111a.

A first active layer 134a of the driving transistor DT can be disposed above the active buffer layer 111b.

A first gate insulating film 112a can be disposed on the first active layer 134a.

Further, a first gate electrode 131a of the driving transistor DT can be disposed on the first gate insulating film 112a.

Further, for example, a gate material layer 136a can be disposed on the first gate insulating film 112a in a position different from a forming position of the driving transistor DT. For example, the gate material layer 136a can be a first storage electrode, but is not limited thereto.

The first interlayer insulating film 113a can be disposed on the first gate electrode 131a.

A metal layer 136b can be disposed on the first interlayer insulating film 113a. For example, the material layer 136b can be a second storage electrode, but is not limited thereto.

In this case, the metal layer 136b can configure the storage capacitor together with the gate material layer 136a, but is not limited thereto.

Further, for example, a second light shielding layer 135b can be disposed on the first interlayer insulating film 113a in a position different from a forming position of the metal layer 136b.

The buffer layer 111c can be disposed on the metal layer 136b and the second light shielding layer 135b.

A second active layer 134b of the switching transistor ST can be disposed on the buffer layer 111c.

A second gate insulating film 112b can be disposed on the second active layer 134b.

Further, a second gate electrode 131b of the switching transistor ST can be disposed on the second gate insulating film 112b.

The second interlayer insulating film 113b can be disposed on the second gate electrode 131b.

A first source electrode 132a and a first drain electrode 133a of the driving transistor DT can be disposed on the second interlayer insulating film 113b. Further, a second source electrode 132b and a second drain electrode 133b of the switching transistor ST can be disposed on the second interlayer insulating film 113b.

For example, the first source electrode 132a and the first drain electrode 133a can be electrically connected to one side and the other side of the first active layer 134a through contact holes provided in the second interlayer insulating film 113b, the second gate insulating film 112b, the buffer layer 111c, the first interlayer insulating film 113a, and the first gate insulating film 112a.

Further, for example, a part of the first drain electrode 133a can be electrically connected to one side of the first light shielding layer 135a through contact holes provided in the second interlayer insulating film 113b, the second gate insulating film 112b, the buffer layer 111c, the first interlayer insulating film 113a, the first gate insulating film 112a, the active buffer layer 111b, and the multi-buffer layer 111a.

For example, the second source electrode 132b and the second drain electrode 133b can be electrically connected to one side and the other side of the second active layer 134b, through contact holes provided in the second interlayer insulating film 113b and the second gate insulating film 112b, respectively.

A part of the first active layer 134a which overlaps the first gate electrode 131a is a channel region. For example, one of the first source electrode 132a and the first drain electrode 133a is connected to one side of the channel region in the first active layer 134a and the other one can be connected to the other side of the channel region in the first active layer 134a.

Further, a part of the second active layer 134b which overlaps the second gate electrode 131b is a channel region. For example, one of the second source electrode 132b and the second drain electrode 133b is connected to one side of the channel region in the second active layer 134b and the other one can be connected to the other side of the channel region in the second active layer 134b.

A passivation film is disposed on the first source electrode 132a, the first drain electrode 133a, the second source electrode 132b, and the second drain electrode 133b.

The planarization layers 115a and 115b can be disposed above the first source electrode 132a, and the first drain electrode 133a and the second source electrode 132b and the second drain electrode 133b. For example, the planarization layers 115a and 115b can include a first planarization layer 115a and a second planarization layer 115b.

The first planarization layer 115a can be disposed on the passivation film.

The connection electrode 137 can be disposed on the first planarization layer 115a. For example, the connection electrode 137 can be electrically connected to one of the first source electrode 132a and the first drain electrode 133a through a contact hole provided in the first planarization layer 115a.

The second planarization layer 115b can be disposed on the connection electrode 137.

A third planarization layer 115c can be disposed on the second planarization layer 115b. The third planarization layer 115c can be configured by an organic material, such as acrylic-based resin or epoxy-based resin, and for example, can be configured by photo acryl (PAC). The first planarization layer 115a, the second planarization layer 115b, and the t third planarization layer 115c can be referred to as overcoat layers.

For example, the third planarization layer 115c can include a first open area OA1 obtained by removing (opening) a part corresponding to a main emission area EA1, a reflective emission area EA2, and a non-emission area NEA of the sub pixel.

In the plan view, the first open area OA1 can have an approximately (or overall) rectangular shape, but is not limited thereto. For example, the first open area OA1 of the present disclosure can have a circular shape, an oval shape, or a plurality of polygonal shapes.

The third planarization layer 115c can include a top surface and a side portion.

The top surface of the third planarization layer 115c is a surface located at the top of the third planarization layer 115c and is substantially parallel to the second substrate 110b.

Further, the side portion of the third planarization layer 115c is a surface extending from the top surface of the third planarization layer 115c to a side surface. For example, a side portion of the third planarization layer 115c can have a predetermined taper angle. For example, the side portion of the third planarization layer 115c can have a taper angle of 30° to 65°, but is not limited thereto.

In the plan view, the side portion of the third planarization layer 115c can have a rectangular shape, like the edge of the first open area OA1, but is not limited thereto. The side portion of the third planarization layer 115c of the present disclosure can have a circular shape, an oval shape, or a plurality of polygonal shapes.

For example, the anode electrode 121 can be disposed on the top surface and the side portion of the third planarization layer 115c and the top surface of the second planarization layer 115b. For example, the anode electrode 121 can be disposed on the first open area OA1 and the top surface and the side portion of the third planarization layer 115c.

Further, for example, the anode electrode 121 which is disposed in the first open area OA1 can be in contact with the top surface of the second planarization layer 115b.

Furthermore, for example, the anode electrode 121 can include a first area 121a which has a surface substantially parallel to a surface of the second substrate 110b in the first open area OA1 and a second area 121b which extends from the first area 121a so that a surface has a predetermined angle with respect to the second substrate 110b. Further, for example, the first area 121a of the anode electrode 121 can correspond to the first open area OA1. For example, the second area 121b of the anode electrode 121 can correspond to a side portion of the third planarization layer 115c. Therefore, the second area 121b of the anode electrode 121 can be referred to as a side portion of the anode electrode 121.

In the present disclosure, the second area 121b of the anode electrode 121 is a part having a side mirror shape and configures the SM structure. The SM structure can have a mirror structure which enables side light reflection by forming the anode electrode 121 after forming the third planarization layer 115c. In the SM structure, a light reflection layer which induces reflection of light emitted from the light emitting diode 120, for example, a second area 121b of the anode electrode 121 is formed on a side portion of the third planarization layer 115c to re-reflect light having a light path which is directed to the second area 121b of the anode electrode 121. By doing this, the front luminance can be improved. The structure is applied in the same way according to the viewing angle so that the luminance versus angle (LvA) characteristic according to the viewing angle condition can be improved.

The SM structure of the anode electrode 121 can be configured in the first open area OA1. The SM structure of the anode electrode 121 can form a reflective emission area EA2. The reflective emission area EA2 follows an outline of the main emission area EA1 and for example, can have a continuous rectangular frame shape or a rectangular frame shape with breaks. In the case of the rectangular frame shape with breaks, the reflective emission area can enclose the outline of the main emission area EA1 and have breaks in the middle. However, the present disclosure is not limited to the shape of the reflective emission area EA2.

As described above, the SM structure configured in the first open area OA1 forms the reflective emission area EA2. A part of light emitted by the light emitting diode 120 is reflected from the second area 121b of the anode electrode 121 by the SM structure to form a rectangular frame-shaped reflective emission area EA2. Therefore, the luminous efficiency can be improved.

For example, according to the first example embodiment of the present disclosure, in the plan view, the main emission area EA1 can have an approximately rectangular shape and the non-emission area NEA can have an approximately rectangular frame shape which encloses the main emission area EA1. The reflective emission area EA2 can have an approximately rectangular frame shape which encloses the main emission area EA1 and the non-emission area NEA. Further, the reflective emission area EA2 can be enclosed by the first non-emission area NEA1 provided between the sub pixels SP1, SP2, and SP3.

Referring to FIGS. 4 and 5, the anode electrode 121 can further include a third area 121c which extends from the second area 121b so that a surface is substantially parallel to a surface of the second substrate 110b. The third area 121c can correspond to the top surface of the third planarization layer 115c.

As described above, in one sub pixel, the second planarization layer 115b and the third planarization layer 115c can include at least one contact hole spaced apart from the first open area OA1. Therefore, the driving transistor DT and the anode electrode 121 of the light emitting diode 120 can be electrically connected through a contact hole.

The bank 116 can be disposed to cover the anode electrode 121.

The bank 116 can cover the second area 121b and the third area 121c of the anode electrode 121. Further, the bank 116 can cover a part of the first area 121a of the anode electrode 121. For example, the bank 116 can cover a part of the edge of the first area 121a of the anode electrode 121.

A part of the bank 116 corresponding to an emission area of the sub pixel can be open.

For example, the bank 116 can include a second open area OA2 obtained by removing (opening) a part corresponding to the main emission area EA1 of each sub pixel.

The first open area OA1 can have a larger width than that of the second open area OA2. For example, in the plan view, the second open area OA2 can have a rectangular shape, but is not limited thereto and can have a circular shape, an oval shape, or a plurality of polygonal shapes.

In the meantime, the main emission area EA1 can have a shape corresponding to a shape of the second open area OA2. When a shape of an arbitrary component corresponds to a shape of the other component, it can mean that the shape of the arbitrary component has the same shape as the other component, or has the same shape, but has a different size, or a shape of the arbitrary component is formed by transferring the shape of the other component by an arbitrary method. Accordingly, the shape of the main emission area EA1 can be substantially understood to be obtained by transferring a shape of the second open area OA2 by light emitted from the organic layer 122 located in the second open area OA2.

Further, the reflective emission area EA2 does not overlap the main emission area EA1 and can be located while enclosing the main emission area EA1.

The reflective emission area EA2 can be a closed curve which encloses the main emission area EA1. Alternatively, the reflective emission area EA2 can have a shape of the closed curve which partially has a break.

The sub pixels can be divided by the main emission area EA1.

Next, the bank 116 includes a top surface, a side portion, and a bottom surface.

For example, the top surface of the bank 116 can be a surface located at the top of the bank 116 and is substantially parallel to the second substrate 110b. Further, the top surface of the bank 116 can correspond to the top surface of the third planarization layer 115c.

A side portion of the bank 116 can be a surface extending from the top surface of the bank 116 to a side surface. The side portion of the bank 116 can have a predetermined taper angle. For example, the side portion of the bank 116 can have a taper angle of 30° to 65°, but is not limited thereto. The side portion of the bank 116 can correspond to the side portion of the third planarization layer 115c.

For example, the bottom surface portion of the bank 116 can correspond to a surface which abuts with the anode electrode 121 in the first area 121a of the anode electrode 121. The bottom surface portion of the bank 116 can correspond to a non-emission area NEA between the main emission area EA1 and the reflective emission area EA2.

The first open area OA1 provided in the third planarization layer 115c can have a width larger than that of the second open area OA2 provided in the bank 116. Therefore, the second open area OA2 can be located in the first open area OA1. For example, a part of the anode electrode 121 can be exposed by the second open area OA2.

The bank 116 can be formed of a PI based material, but is not limited thereto.

A side portion of the bank 116 can have the rectangular shape, like the edge of the second open area OA2, but the present disclosure is not limited thereto. For example, the side portion of the bank 116 of the present disclosure can have a circular shape, an oval shape, or a plurality of polygonal shapes.

In the meantime, according to the first example embodiment of the present disclosure, the recrystallization layer 125 can be disposed above the bank 116. For example, the recrystallization layer 125 can be disposed on the top surface and the side portion of the bank 116 and a part of the top surface of the exposed anode electrode 121.

Here, the recrystallization layer 125 includes a fluoro-group to have hydrophobicity and a low surface energy to suppress permeation of oxygen O₂ or moisture H₂O. Further, due to its high polarity, it can serve as a trap site of polar materials or charges in the outgas components. Therefore, the reliability characteristic can be improved.

For example, the recrystallization layer 125 can be formed by a deposition process or a solution process, such as sputtering.

For example, the recrystallization layer 125 can be configured by a polyfluoroacrylate based organic compound and has a structure of Formula 1 below.

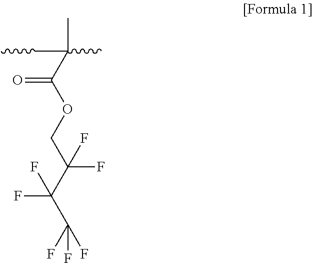

The recrystallization layer 125 can be configured by a polychlorotrifluoroethylene (PCTFE) based organic compound and has a structure of Formula 2 below.

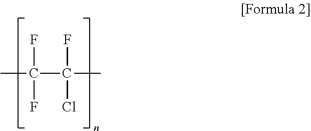

The recrystallization layer 125 can be configured by a polytetrafluoroethylene (PTFE) based organic compound and has a structure of Formula 3 below.

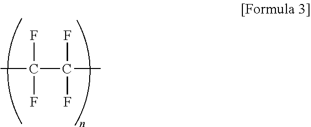

The recrystallization layer 125 can be configured by a perfluorodecyltrichlorosilane (FDTS) based organic compound and has a structure of Formula 4 below.

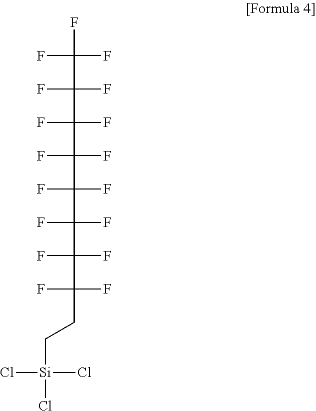 [SMILES: FC(F)(F)C(F)(F)C(F)(F)C(F)(F)C(F)(F)C(F)(F)C(F)(F)C(F)(F)CC[Si](Cl)(Cl)Cl]

The recrystallization layer 125 can be configured by a polyvinyliden fluoride (PVDF) based organic compound and has a structure of Formula 5 below.

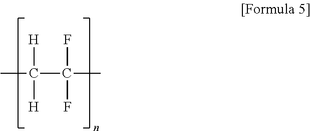

The above-described recrystallization layer 125 is a polymer organic film to have less pin holes than an inorganic film so that in the SM structure, the outgas can be more effectively removed than the second area 121b of the anode electrode 121.

According to the chemical structure of the material of the recrystallization layer 125, the CF₃-group is formed based on the C—F bond so that the surface has a hydrophobic/polar characteristic. The influence on the light emitting diode 120 can be reduced by adsorbing moisture (H₂O) and N-methyl-2-pyrrolidone (NMP) which are outgas components generated during the reliability evaluation or suppressing the permeation thereof.

The fluoroacrylate-based material as the recrystallization layer 125 is applicable to a room temperature/normal pressure coating process in a solution state at a room temperature and has a good solution volatility, which makes it easy to form a solid layer and does not require an additional heat treatment for thinning after coating. Further, the fluoroacrylate solution has an advantage of having low reactivity with an organic material, wide selectivity for a solvent, and less restrictions on process application. Further, since a glass transition temperature (Tg) is as low as ˜100° C., the effect of heat on the other layers can be minimized during the additional heat treatment process and the glass transition temperature can be controlled by controlling a composition ratio or a structure during the synthesis. In addition, a fluoroacrylate material which is an organic material has less pin holes than the metal layer which is an inorganic material and is configured by CF₃-group to effectively adsorb or block the outgas to improve the reliability.

The recrystallization layer 125 can be patterned to be disposed only in the vicinity of each sub pixel.

As described above, even though in FIG. 3, an example that the recrystallization layer 125 is formed in the first sub pixel SP1 is illustrated, it is not limited thereto. Therefore, the recrystallization layer 125 can be formed in all the first sub pixel SP1, the second sub pixel SP2, and the third sub pixel SP3 or the recrystallization layer 125 can be formed only in some of the first sub pixel SP1, the second sub pixel SP2, and the third sub pixel SP3.

Further, the organic layer 122 can be disposed in the second open area OA2 of the bank 116 (excluding a portion in which the recrystallization layer 125 is disposed). For example, the organic layer 122 can be disposed on a top surface of the anode electrode 121 exposed through the second open area OA2 of the bank 116. For example, the recrystallization layer 125 can be disposed in the vicinity of the organic layer 122.

The organic layer 122 can be disposed only in the second open area OA2, but the present disclosure is not limited thereto and a part thereof can also be disposed on a top surface and a side portion of the recrystallization layer 125 other than the second open area OA2.

The cathode electrode 123 can be disposed on the organic layer 122 and the recrystallization layer 125.

As described above, the light emitting diode 120 can be configured by the anode electrode 121, the organic layer 122, and the cathode electrode 123.

For example, the main emission area EA1 can be formed by the light emitting diode 120 provided in the second open area OA2.

An encapsulation layer can be disposed above the above-described light emitting diode 120.

At this time, the encapsulation layer can have a single layer structure or a multi-layered structure. For example, the encapsulation layer can include a first encapsulation layer, a second encapsulation layer, and a third encapsulation layer.

For example, the first encapsulation layer and the third encapsulation layer are configured by an inorganic layer and the second encapsulation layer can be configured by an organic layer. For example, among the first encapsulation layer, the second encapsulation layer, and the third encapsulation layer, the second encapsulation layer is the thickest, so that the second encapsulation layer serves as a planarization layer.

The first encapsulation layer can be formed by the inorganic insulating material which can be subject to the low temperature deposition, and for example, can be configured by silicon nitride (SiNx), silicon oxide (SiOx), silicon oxynitride (SiON), or aluminum oxide Al₂O₃.

The second encapsulation layer can be formed to have a smaller area than that of the first encapsulation layer. In this case, the second encapsulation layer can be formed to expose both ends of the first encapsulation layer.

Further, for example, the second encapsulation layer can be configured by an organic insulating material, such as acrylic resin, epoxy resin, polyimide, polyethylene, or silicon oxy carbon (SiOC). Further, for example, the second encapsulation layer can be formed by an inkjet method, but is not limited thereto.

The third encapsulation layer can be formed to cover a top surface and a side surface of each of the second encapsulation layer and the first encapsulation layer.

For example, the third encapsulation layer can minimize or block the permeation of external moisture or oxygen into the first encapsulation layer and the second encapsulation layer.

Further, for example, the third encapsulation layer can be configured by an inorganic insulating material, such as silicon oxide (SiOx), silicon oxynitride (SiON), or aluminum oxide (Al₂O₃), or silicon nitride (SiNx).

A touch sensor layer and/or a color filter layer can be disposed above the above-described encapsulation layer.

According to the present disclosure, the recrystallization layer is subject to a low-temperature heat treatment to increase a surface roughness, thereby improving a front efficiency and a color viewing angle according to the increase of the light extraction, which will be described in detail with reference to the drawing.

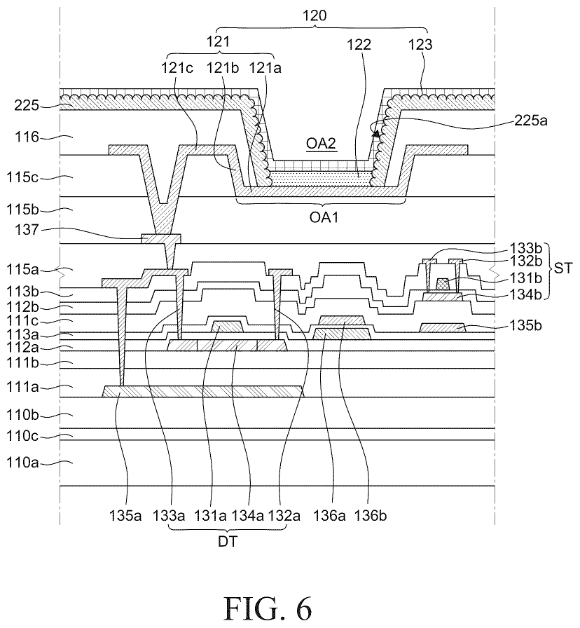

FIG. 6 is a view illustrating a cross-sectional structure of a display panel of a display device according to a second example embodiment of the present disclosure.

The second example embodiment of the present disclosure of FIG. 6 has the substantially same configuration as the first example embodiment of the present disclosure of FIGS. 3 to 5 described above, except that the recrystallization layer 225 is subject to the low temperature heat treatment to increase a surface roughness. Therefore, a redundant description will be omitted or may be briefly provided. The same configuration will be denoted with the same reference numeral. Thus, the description for the same reference numerals in this second embodiment can be understood by referring to the above description associated with FIGS. 1 to 5.

Particularly, FIG. 6 illustrates a part of a cross-section of one sub pixel of the display panel, where each sub pixel of the display panel can have the configuration of FIG. 6.

Even though in FIG. 6, components above the light emitting diode 120 are not illustrated for the convenience of description, the present disclosure is not limited thereto and the present disclosure can include an encapsulation layer and a touch sensor layer above the light emitting diode 120.

Referring to FIG. 6, the driving transistor DT, the switching transistor ST, and the light emitting diode 120 can be disposed above substrates 110a, 110b, and 110c. The detailed description of the driving transistor DT, the switching transistor ST, and the light emitting diode 120 can refer to the above-described first example embodiment.

The first planarization layer 115a and the second planarization layer 115b can be disposed above the driving transistor DT and the switching transistor ST.

Further, a third planarization layer 115c can be disposed on the second planarization layer 115b.

For example, the third planarization layer 115c can include a first open area OA1 obtained by removing (opening) a part corresponding to a main emission area EA1, a reflective emission area EA2, and a non-emission area NEA of the sub pixel.

The third planarization layer 115c can include a top surface and a side portion.

The top surface of the third planarization layer 115c can be a surface located at the top of the third planarization layer 115c and is substantially parallel to the second substrate 110b.

Further, the side portion of the third planarization layer 115c can be a surface extending from the top surface of the third planarization layer 115c to a side surface.

For example, the anode electrode 121 can be disposed on the top surface and the side portion of the third planarization layer 115c and the top surface of the second planarization layer 115b. For example, the anode electrode 121 can be disposed on the first open area OA1 and the top surface and the side portion of the third planarization layer 115c.

In addition, for example, the anode electrode 121 which is disposed in the first open area OA1 can be in contact with the top surface of the second planarization layer 115b.

Furthermore, for example, the anode electrode 121 can include a first area 121a which has a surface substantially parallel to a surface of the second substrate 110b in the first open area OA1 and a second area 121b which extends from the first area 121a so that a surface has a predetermined angle with respect to the second substrate 110b. Further, for example, the first area 121a of the anode electrode 121 can correspond to the first open area OA1. For example, the second area 121b of the anode electrode 121 can correspond to a side portion of the third planarization layer 115c.

As described above, in the present disclosure, the second area 121b of the anode electrode 121 configures the SM structure and the SM structure of the anode electrode 121 can form the reflective emission area EA2.

As described above, a part of light emitted by the light emitting diode 120 is reflected from the second area 121b of the anode electrode 121 by the SM structure to additionally form a reflective emission area EA2. Therefore, the luminous efficiency can be improved.

The anode electrode 121 can further include a third area 121c which extends from the second area 121b so that a surface is substantially parallel to a surface of the second substrate 110b. The third area 121c can correspond to the top surface of the third planarization layer 115c.

The bank 116 can be disposed to cover the anode electrode 121.

The bank 116 can cover the overall second area 121b and the overall third area 121c of the anode electrode 121 and a part of the edge of the first area 121a.

For example, the bank 116 can include a second open area OA2 obtained by removing (opening) a part corresponding to the main emission area EA1 of each sub pixel.

The main emission area EA1 can have a shape corresponding to a shape of the second open area OA2. Further, the reflective emission area EA2 does not overlap the main emission area EA1 and can be located while enclosing the main emission area EA1.

The sub pixels can be divided by the main emission area EA1.

Next, the bank 116 can include a top surface, a side portion, and a bottom surface.

For example, the top surface of the bank 116 can be a surface located at the top of the bank 116 and is substantially parallel to the second substrate 110b. Further, the top surface of the bank 116 can correspond to the top surface of the third planarization layer 115c.

A side portion of the bank 116 can be a surface extending from the top surface of the bank 116 to a side surface. The side portion of the bank 116 can have a predetermined taper angle.

For example, the bottom surface portion of the bank 116 can correspond to a surface which abuts with the anode electrode 121 in the first area 121a of the anode electrode 121. The bottom surface portion of the bank 116 can correspond to a non-emission area NEA between the main emission area EA1 and the reflective emission area EA2.

For example, a part of the anode electrode 121 can be exposed by the second open area OA2.

In the meantime, according to the second example embodiment of the present disclosure, the recrystallization layer 225 can be disposed above the bank 116. For example, the recrystallization layer 225 can be disposed on the top surface and the side portion of the bank 116 and a part of a top surface of the exposed anode electrode 121.

As described above, the recrystallization layer 225 includes a fluoro-group to have hydrophobicity and a low surface energy to suppress permeation of oxygen O₂ or moisture H₂O. Further, due to its high polarity, it can serve as a trap site of polar materials or charges in the outgas components. Therefore, the reliability characteristic can be improved.

For example, the recrystallization layer 225 can be formed by a deposition process or a solution process, such as sputtering.

As described above, the recrystallization layer 225 can be configured by fluoroacrylate based, PCTFE based, PTFE based, FDTS based, or PVDF based organic compound.

The recrystallization layer 225 can be patterned to be disposed only in the vicinity of each sub pixel.

The recrystallization layer 225 can be formed in all the first sub pixel SP1, the second sub pixel SP2, and the third sub pixel SP3 or formed only in some of the first sub pixel SP1, the second sub pixel SP2, and the third sub pixel SP3.

According to the second example embodiment of the present disclosure, the recrystallization layer 225 is subject to the low temperature heat treatment so that the surface roughness is increased. For example, when the low temperature heat treatment is applied to the recrystallization layer 225, intermolecular aggregation is induced to increase the roughness of the surface. When the surface roughness is increased as described above, the light path is scattered to improve the light extraction. For example, according to the first example embodiment described above, light reflected from the second area 121b on the side surface of the SM structure is totally reflected by being absorbed or trapped by the bank 116 or the difference in refractive indexes of the bank 116 and the recrystallization layer 125, which can cause the loss of light.

In contrast, according to the second example embodiment, a structure 225a is formed on the surface of the recrystallization layer 225 of the side surface of the SM structure to significantly increase the surface roughness so that the light path is scattered to improve the light extraction. Accordingly, as compared with the first example embodiment, the front luminance (efficiency) and the side luminance (luminance viewing angle) can be further improved. For example, when the recrystallization layer 125 of the present disclosure is applied to all the red sub pixel SP1, the green sub pixel SP2, and the blue sub pixel SP3, it is understood that the luminance is increased with a predetermined ratio without changing a color coordinate for each color. For example, it was understood that the luminance is increased by approximately 5% as compared with the display device before being applied, but the LvA characteristic is the same level.

Therefore, when the present disclosure is selectively applied for each color, for example, each of the red sub pixel SP1, the green sub pixel SP2, and the blue sub pixel SP3, a level of luminance improvement and a visual characteristic can be controlled. For example, when the present disclosure is applied to the red sub pixel SP1, the luminance is improved by approximately 1.1% based on the white luminance and a reddish visual characteristic can be ensured. When the present disclosure is applied to the green sub pixel SP2, the luminance is improved by approximately 3.5% based on the white luminance and a greenish visual characteristic can be ensured. Further, when the present disclosure is applied to the blue sub pixel SP3, the luminance is improved by approximately 0.4% based on the white luminance and a bluish visual characteristic can be ensured.

As described above, the material of the recrystallization layer 225 described above has a low glass transition temperature so that the surface roughness of the recrystallization layer 225 can be controlled by the low temperature heat treatment. For example, when the surface roughness of the recrystallization layer 225 is increased, the light path can be randomly controlled according to a surface state to induce the light scattering, which can maximize the light extraction effect.

Further, the above-described material of the recrystallization layer 225 has a low glass transition temperature so that it is advantageous to minimize the influence of heat on the other layer during an additional heat treatment process.

When the surface roughness of the surface of the recrystallization layer 225 above the bank 116 is increased, a lateral leakage current is reduced to improve a low gray scale characteristic. In the related art, a lateral leakage current flows from an anode electrode of a specific sub pixel to an anode electrode of an adjacent sub pixel and specifically, is significant between the red sub pixel and the green sub pixel and between the red sub pixel and the blue sub pixel having a relatively high turn-on voltage difference. Therefore, according to the second example embodiment of the present disclosure, the recrystallization layer 225 is formed only above the bank 116 of the red sub pixel SP1 to perform the heat treatment or the heat treatment is performed only on the recrystallization layer 225 above the bank 116 of the red sub pixel SP1. By doing this, the lateral leakage current can be reduced by increasing a movement path of a current flowing from the red sub pixel SP1 to the green sub pixel SP2 or the blue sub pixel SP3 or a current flowing from the green sub pixel SP2 or the blue sub pixel SP3 to the red sub pixel SP1. Further, the above-described material of the recrystallization layer 225 includes the fluoro-group to serve as a trap site of the charge, which can further reduce the lateral leakage current.

Further, the organic layer 122 can be disposed in the second open area OA2 of the bank 116 (excluding a portion in which the recrystallization layer 225 is disposed). For example, the organic layer 122 can be disposed on a top surface of the anode electrode 121 exposed through the second open area OA2 of the bank 116. For example, the recrystallization layer 225 can be disposed in the vicinity of the organic layer 122.

The organic layer 122 can be disposed only in the second open area OA2, but the present disclosure is not limited thereto and a part thereof can also be disposed on a top surface and a side portion of the recrystallization layer 225 other than the second open area OA2.

The cathode electrode 123 can be disposed on the organic layer 122 and the recrystallization layer 225. The organic layer 122 and the cathode electrode 123 can have a surface shape according to the surface roughness of the recrystallization layer 225.

According to the present disclosure, the heat-treated recrystallization layer is formed only on the top surface of the bank or the heat treatment is performed only on the recrystallization layer on the top surface of the bank. Further, the heat-treated recrystallization layer is formed only in the side portion of the bank or the heat treatment is performed only on the recrystallization layer in the side portion of the bank. This will be described in detail with reference to the drawings.

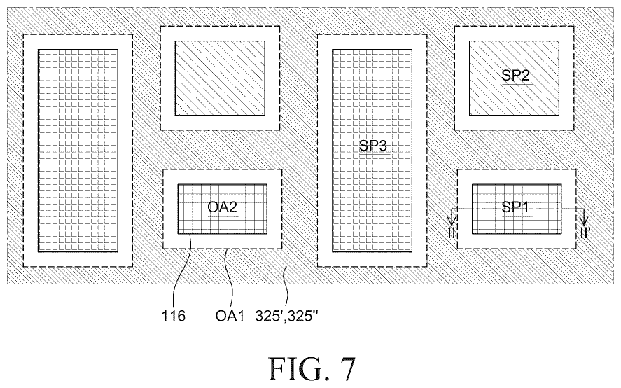

FIG. 7 is a view illustrating a pixel structure of a display device according to a third example embodiment of the present disclosure.

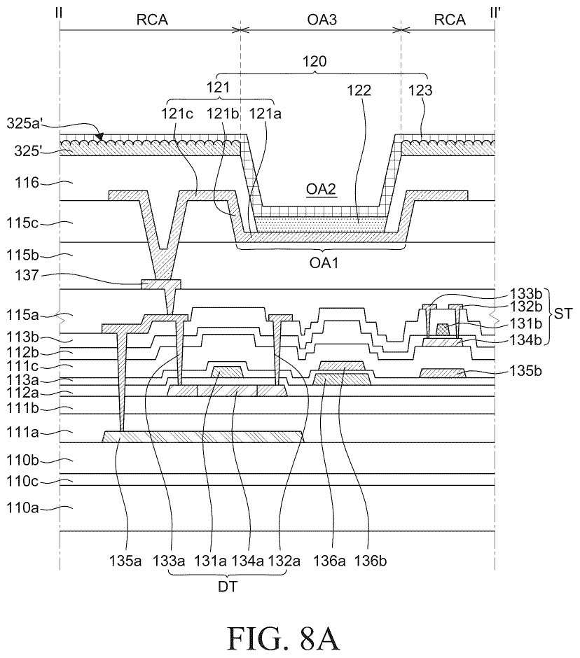

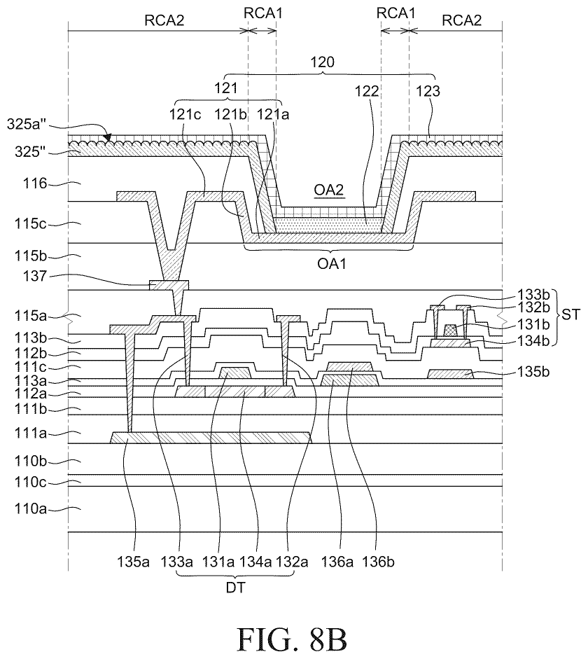

FIGS. 8A and 8B are views illustrating a cross-section of a display panel of the display device according to the third example embodiment of the present disclosure.

According to the third example embodiment of the present disclosure of FIGS. 7, 8A, and 8B, a heat-treated recrystallization layer 325′ is formed only on a top surface of the bank 116 or the heat treatment is performed only on a recrystallization layer 325″ on the top surface of the bank 116, which is different from the first example embodiment of FIGS. 3 to 5 and/or the second example embodiment of FIG. 6 described above. However, the other configurations are substantially the same so that a redundant description will be omitted or may be briefly provided. The same configuration will be denoted with the same reference numeral. Here, the description for the same reference numerals in this embodiment can be understood by referring to the above-provided description in connection with FIGS. 1 to 6.

Particularly, FIG. 7 illustrates a part of a display panel in which six sub pixels SP1, SP2, and SP3 are disposed and illustrates a bank 116 including a second open area OA2 which is a main emission area, a first open area OA1 including a main emission area and a reflective emission area, and a recrystallization layer 325′, 325″. In the plan view, the area of the recrystallization layer 325′, 325″ on which the heat treatment is performed can at least partially overlap a recrystallization layer area RCA or a second recrystallization layer area RCA2. For example, the heat-treated recrystallization layer 325′, 325″ can be formed so as not to overlap the second open area OA2 of the bank 116 in the side portion (see FIGS. 8A and 8B).

FIGS. 8A and 8B illustrate a part of a cross-section of one sub pixel taken along line II-II′ of FIG. 7. Even though in FIGS. 8A and 8B, components above the light emitting diode 120 are not illustrated for the sake of convenience, the present disclosure is not limited thereto and the present disclosure may include an encapsulation layer, a touch sensor layer, and a color filter layer above the light emitting diode 120.

Further, FIG. 8A illustrates an example of the third example embodiment that the heat-treated recrystallization layer 325′ is formed only on a top surface of the bank 116. FIG. 8B illustrates another example of the third example embodiment that the heat treatment is performed only on the recrystallization layer 325″ of the top surface of the bank 116.

Referring now to FIGS. 7, 8A, and 8B, the driving transistor DT, the switching transistor ST, and the light emitting diode 120 can be disposed above substrates 110a, 110b, and 110c. The detailed description of the driving transistor DT, the switching transistor ST, and the light emitting diode 120 can refer to the above-described first example embodiment.

According to the third example embodiment of the present disclosure, the recrystallization layer 325′, 325″ can be disposed above the bank 116. For example, the recrystallization layer 325′ can be disposed only on the top surface of the bank 116 (see FIG. 8A) and the recrystallization layer 325″ can be disposed on the top surface and the side portion of the bank 116 and a part of the top surface of the exposed anode electrode 121 (see FIG. 8B). In the case of the example embodiment of FIG. 8A, in the plan view, the recrystallization layer 325′ can be disposed above the bank 116 excluding a third open area OA3 which overlaps the second open area OA2 of the bank 116 in the side portion. For example, the recrystallization layer 325′ can have a recrystallization layer area RCA which encloses the third open area OA3. In the case of the example embodiment of FIG. 8B, in the plan view, the recrystallization layer 325″ has a first recrystallization layer area RCA1 which encloses the second open area OA2 of the bank 116 and a heat-treated second recrystallization layer area RCA2 which encloses the first recrystallization layer area RCA1. For example, the first recrystallization layer area RCA1 corresponds to a side portion of the bank 116 and the second recrystallization layer area RCA2 can correspond to a part of a top surface of the bank 116.

As described above, the recrystallization layer 325′, 325″ can be configured by fluoroacrylate based, PCTFE based, PTFE based, FDTS based, or PVDF based organic compound containing a fluoro-group.

The recrystallization layer 325′, 325″ can be patterned to be disposed only in the vicinity of each sub pixel.

The recrystallization layer 325′, 325″ can be formed in all the first sub pixel SP1, the second sub pixel SP2, and the third sub pixel SP3 or formed only in some of the first sub pixel SP1, the second sub pixel SP2, and the third sub pixel SP3.

According to the third example embodiment of the present disclosure, the recrystallization layer 325′, 325″ is subject to the low temperature heat treatment so that the surface roughness is increased. For example, the heat treatment can be performed in the recrystallization layer 325′ which is formed only on the top surface of the bank 116 (see FIG. 8A) and the heat treatment can be performed only on the recrystallization layer 325″ formed on the top surface of the bank 116 (see FIG. 8B). In this case, a structure 325a′ can be formed on a surface of the recrystallization layer 325′ which is formed only on the top surface of the bank 116 (see FIG. 8A) and a structure 325a″ is formed only on the surface of the recrystallization layer 325″ formed on the top surface of the bank 116 (see FIG. 8B) to significantly increase the surface roughness.

As in the third example embodiment of the present disclosure, when the recrystallization layer 325′, 325″ having the structures 325a′, 325a″ is applied only to the top surface of the bank 116, it is advantageous to control the lateral leakage current related to the low gray scale characteristic rather than the improvement of the luminance and the color viewing angle. In this case, it is not necessary to apply the recrystallization layer to all the first sub pixel SP1, the second sub pixel SP2, and the third sub pixel SP3, but can be selectively applied only to the first sub pixel SP1 which is the red sub pixel having a relatively high leakage current.

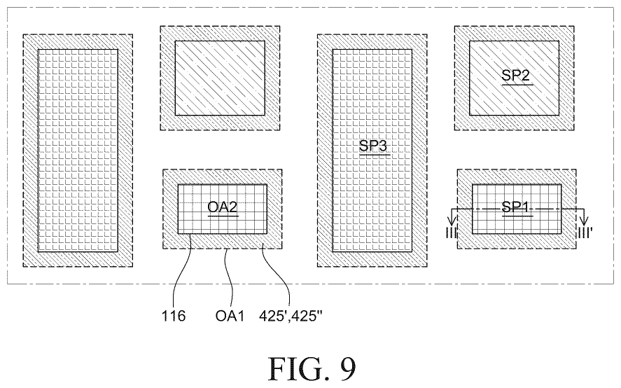

FIG. 9 is a view illustrating a pixel structure of a display device according to a fourth example embodiment of the present disclosure.

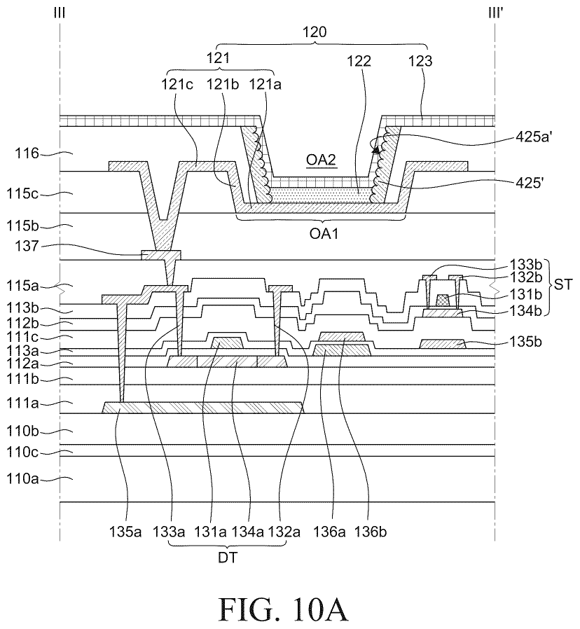

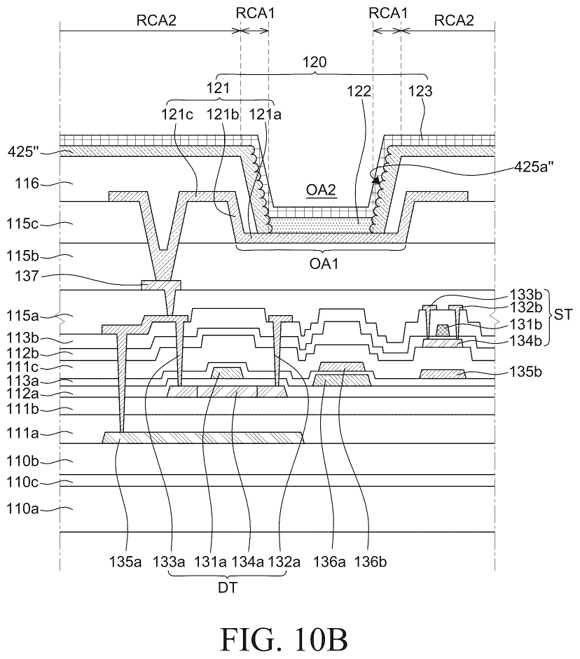

FIGS. 10A and 10B are views illustrating a cross-section of a display panel of the display device according to the fourth example embodiment of the present disclosure.

According to the fourth example embodiment of the present disclosure of FIGS. 9, 10A, and 10B, a heat-treated recrystallization layer 425′ is formed only on a side portion of the bank 116 or the heat treatment is performed only on a recrystallization layer 425″ of a side portion of the bank 116, which is different from the first example embodiment of FIGS. 3 to 5 and/or the second example embodiment of FIG. 6. However, the other configurations are substantially the same so that a redundant description will be omitted or may be briefly provided. The same configuration will be denoted with the same reference numeral. Here, the description for the same reference numerals in this embodiment can be understood by referring above to the description associated with FIGS. 1 to 6.

Particularly, FIG. 9 illustrate a part of the display panel in which six sub pixels SP1, SP2, and SP3 are disposed and illustrates a bank 116 including a second open area OA2 which is a main emission area, a first open area OA1 including a main emission area and a reflective emission area, and a recrystallization layer 425′, 425″.

FIGS. 10A and 10B illustrate a part of a cross-section of one sub pixel taken along line III-III′ of FIG. 9. Even though in FIGS. 10A and 10B, components above the light emitting diode 120 are not illustrated for the sake of convenience, the present disclosure is not limited thereto and the present disclosure can include an encapsulation layer, a touch sensor layer, and a color filter layer above the light emitting diode 120.

Further, FIG. 10A illustrates an example of the fourth embodiment that the heat-treated recrystallization layer 425′ is formed only on a side portion of the bank 116. FIG. 10B illustrates another example of the fourth embodiment that the heat treatment is performed only on the recrystallization layer 425″ of the side portion of the bank 116. In this case, in the plan view, the recrystallization layer (425′, 425″) area on which the heat treatment is performed can overlap the non-emission area NEA and the reflective emission area EA2 and can have a border band shape which encloses the main emission area EA1 of each sub pixel SP1, SP2, SP3.

Referring now to FIGS. 9, 10A, and 10B, the driving transistor DT, the switching transistor ST, and the light emitting diode 120 can be disposed above substrates 110a, 110b, and 110c. The detailed description of the driving transistor DT, the switching transistor ST, and the light emitting diode 120 can refer to the above-described first example embodiment.

According to the fourth example embodiment of the present disclosure, the recrystallization layer 425′, 425″ can be disposed above the bank 116. For example, the recrystallization layer 425′ can be disposed only in the side portion of the bank 116 (see FIG. 10A) and the recrystallization layer 425″ can be disposed on the top surface and the side portion of the bank 116 and a part of the top surface of the exposed anode electrode 121 (see FIG. 10B). In the case of the example embodiment of FIG. 10B, in the plan view, the recrystallization layer 425″ can have a heat-treated first recrystallization layer area RCA1 which encloses the second open area OA2 of the bank 116 and a second recrystallization layer area RCA2 which encloses the heat-treated first recrystallization layer area RCA1. For example, the first recrystallization layer area RCA1 can correspond to a side portion of the bank 116 and the second recrystallization layer area RCA2 can correspond to a part of a top surface of the bank 116. As described above, the recrystallization layer 425′, 425″ can be configured by a fluoroacrylate based organic compound, a PCTFE based organic compound, a PTFE based organic compound, a FDTS based organic compound, or a PVDF based organic compound containing a fluoro-group.

The recrystallization layer 425′, 425″ can be patterned to be disposed only in the vicinity of each sub pixel.

The recrystallization layer 425′, 425″ can be formed in all the first sub pixel SP1, the second sub pixel SP2, and the third sub pixel SP3 or formed only in some of the first sub pixel SP1, the second sub pixel SP2, and the third sub pixel SP3.

According to the fourth example embodiment of the present disclosure, the recrystallization layer 425′, 425″ is subject to the low temperature heat treatment so that the surface roughness is increased. For example, the heat treatment can be performed in the recrystallization layer 425′ which is formed only in the side portion of the bank 116 (see FIG. 10A) and the heat treatment can be performed only on the recrystallization layer 425″ formed in the side portion of the bank 116 (see FIG. 10B). In this case, a structure 425a′ can be formed on a surface of the recrystallization layer 425′ which is formed only in the side portion of the bank 116 (see FIG. 10A) and a structure 425a″ is formed only on the surface of the recrystallization layer 425″ formed in the side portion of the bank 116 (see FIG. 10B) to significantly increase the surface roughness.

As in the fourth example embodiment of the present disclosure, when the recrystallization layer 425′, 425″ having the structure 425a′, 425a″ is applied only to the side portion of the bank 116, it is more advantageous to improve the luminance and the color viewing angle rather than the leakage current related to the low gray scale characteristic. When degradation the low gray scale characteristic due to the leakage current is not severe, the effect of increasing a charge transport path by the surface roughness is excluded, but only the charge trap effect by the recrystallization layer material (CF₃-group) is implemented to lower the leakage current.

The example embodiments of the present disclosure can also be described as follows:

According to an aspect of the present disclosure, there is provided a display device. The display device includes a substrate including a plurality of sub pixels, a planarization layer which is disposed above the substrate and has a first open area, an anode electrode disposed in the first open area and a side portion of the planarization layer adjacent to the first open area, a bank which exposes a part of the anode electrode and has a second open area corresponding to the first open area, a recrystallization layer disposed on the bank and including a fluoro-group, an organic layer disposed on the anode electrode exposed by the second open area and a cathode electrode disposed on the organic layer and the recrystallization layer.

The first open area can have a width larger than that of the second open area.

The anode electrode can partially extend from the side portion of the planarization layer to a top surface of the planarization layer.

The anode electrode can have a side portion corresponding to the side portion of the planarization layer.

The anode electrode, the organic layer, and the cathode electrode can configure a light emitting diode, the light emitting diode can form a main emission area, the side portion of the anode electrode can form a reflective emission area, the reflective emission area can be formed in the vicinity of the main emission area, and a non-emission area can be formed between the main emission area and the reflective emission area.

The recrystallization layer can be provided in all the sub pixels.

The recrystallization layer can be provided in some sub pixels.

The recrystallization layer can be disposed on a top surface and a side portion of the bank and a part of a top surface of the exposed anode electrode.

The recrystallization layer can be configured by a polychlorotrifluoroethylene (PCTFE) based organic compound, a polytetrafluoroethylene (PTFE) based organic compound, a perfluorodecyltrichlorosilane (FDTS) based organic compound, a polyvinyliden fluoride (PVDF) based organic compound, or polyfluoroacrylate based organic compound.

The organic layer maybe disposed in the second open area of the bank excluding a part in which the recrystallization layer is disposed.

A surface roughness of the recrystallization layer can be increased by low temperature heat treatment.

The recrystallization layer can include a structure with an increased surface roughness on a surface of the planarization layer.

The recrystallization layer can be disposed only on the top surface of the bank and can include a structure with an increased surface roughness on a surface of the planarization layer.

The recrystallization layer can be disposed on a top surface and a side portion of the bank and a part of a top surface of the exposed anode electrode and can include a structure with an surface and a side portion of the bank and a part of a top surface of the exposed anode electrode and can include a structure with an increased surface roughness only on a surface of the recrystallization layer formed on the top surface of the bank.

The recrystallization layer can be disposed only in a side portion of the bank and can include a structure with an increased surface roughness on a surface of the planarization layer.

The recrystallization layer can be disposed on a top surface and a side portion of the bank and a part of a top surface of the exposed anode electrode and can include a structure with an increased surface roughness only a surface of the on recrystallization layer formed on the side portion of the bank.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including a plurality of sub pixels;
a planarization layer disposed on the substrate and including a first open area;
an anode electrode disposed in the first open area and a side portion of the planarization layer adjacent to the first open area;
a bank configured to expose a part of the anode electrode and including a second open area corresponding to the first open area;
a recrystallization layer disposed on the bank and including a fluoro-group;
an organic layer disposed on the anode electrode exposed by the second open area; and
a cathode electrode disposed on the organic layer and the recrystallization layer.

2. The display device according to claim 1, wherein the first open area of the planarization layer has a width larger than a width of the second open area of the bank.

3. The display device according to claim 1, wherein the anode electrode partially extends from the side portion of the planarization layer to a top surface of the planarization layer.

4. The display device according to claim 1, wherein the anode electrode has a side portion corresponding to the side portion of the planarization layer.

5. The display device according to claim 4, wherein the anode electrode, the organic layer, and the cathode electrode configure a light emitting diode,
wherein the light emitting diode forms a main emission area,
wherein the side portion of the anode electrode forms a reflective emission area,
wherein the reflective emission area is formed in a vicinity of the main emission area, and
wherein a non-emission area is formed between the main emission area and the reflective emission area.

6. The display device according to claim 1, wherein the recrystallization layer is provided in all of the plurality of sub pixels.

7. The display device according to claim 1, wherein the recrystallization layer is provided in some of the plurality of sub pixels.

8. The display device according to claim 1, wherein the recrystallization layer is disposed on a top surface and a side portion of the bank and a part of a top surface of the exposed anode electrode.

9. The display device according to claim 1, wherein the recrystallization layer is configured by a polychlorotrifluoroethylene (PCTFE) based organic compound, a polytetrafluoroethylene (PTFE) based organic compound, a perfluorodecyltrichlorosilane (FDTS) based organic compound, a polyvinyliden fluoride (PVDF) based organic compound, or a polyfluoroacrylate based organic compound.

10. The display device according to claim 1, wherein the organic layer is disposed in the second open area of the bank excluding a part in which the recrystallization layer is disposed.

11. The display device according to claim 1, wherein a surface roughness of the recrystallization layer is increased by low temperature heat treatment.

12. The display device according to claim 1, wherein the recrystallization layer includes a structure with an increased surface roughness on a surface of the recrystallization layer.

13. The display device according to claim 1, wherein the recrystallization layer is disposed only on a top surface of the bank, and includes a structure with an increased surface roughness on a surface of the recrystallization layer.

14. The display device according to claim 1, wherein the recrystallization layer is disposed on a top surface and a side portion of the bank and a part of a top surface of the exposed anode electrode, and includes a structure with an increased surface roughness only on a surface of the recrystallization layer formed on the top surface of the bank.

15. The display device according to claim 1, wherein the recrystallization layer is disposed only in a side portion of the bank, and includes a structure with an increased surface roughness on a surface of the recrystallization layer.

16. The display device according to claim 1, wherein the recrystallization layer is disposed on a top surface and a side portion of the bank and a part of a top surface of the exposed anode electrode, and includes a structure with an increased surface roughness only on a surface of the recrystallization layer formed on the side portion of the bank.
